(19) United States
(12) Patent Application Publication
(10) Pub. No.: US 2005/0141579 A1
(43) Pub. Date: Jun. 30, 2005

(54) Semiconductor laser and method for fabricating the same

(75) Inventors: Keiji Yamane, Hyogo (JP); Masahiro Kume, Shiga (JP); Toshiya Kawata, Okayama (JP); Isao Kidoguchi, Hyogo (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/980,651

(22) Filed: Nov. 4, 2004

(30) Foreign Application Priority Data
Dec. 25, 2003 (JP) 2003-429470

(51) Int. Cl. H01S 5/00

(52) U.S. Cl. 372/46; 372/45

(57) ABSTRACT

A semiconductor laser includes an n-type semiconductor substrate, an n-type clad layer, an active layer, a p-type first clad layer, a current blocking layer, a p-type second clad layer and a p-type contact layer stacked in this order form the bottom. A p-side ohmic electrode is formed on the p-type contact layer and an n-side ohmic electrode is formed on a back surface of the n-type semiconductor substrate. A stripe is formed in the current blocking layer so as to extend in the optical oscillator direction. In a center portion of the p-type contact layer, a slit is formed so as to extend in the optical oscillator direction and intersect with the stripe with right angles.

### CROSS-REFERENCE TO RELATED APPLICATION

This application claims priority under 35 U.S.C. §119(a) on Japanese Patent Application No. 2003-429470 filed on Dec. 25, 2003, the entire contents of which are hereby incorporated by reference.

### BACKGROUND OF THE INVENTION

1. Field of the Invention

The present invention relates to a semiconductor laser used with a semiconductor laser diode mounted therein, and more particularly relates to measures to reduce distortion generated in a semiconductor laser diode when the semiconductor laser diode is bonded to a submount with a solder material interposed therebetween.

2. Prior Art

In recent years, optical disks such as CDs (compact disks) and DVDs (digital versatile disks) have been accepted as a suitable medium for recording a large capacity of digital information, represented by AV contents information, by public use, and the demand for optical disk systems has been rapidly increased.

A semiconductor laser used for optical pickup is a laser in which a semiconductor laser diode including a semiconductor lamination layer having an active layer stacked on a substrate and an electrode formed on the semiconductor lamination layer is bonded to a submount with a solder material between the semiconductor lamination layer and the submount.

Hereinafter, an example of mounting methods for a known semiconductor laser will be described (e.g., see Japanese Laid-Open Publication No. 2002-217480). FIGS. 12A through 12C are cross-sectional views illustrating a mounting method for the known semiconductor laser.

First, as shown in FIG. 12A, a submount 131 is placed on a heating table 138 and then the submount 131 is heated to a temperature over a level at which a solder material 132 on the submount 131 melts. Meanwhile, a collet 137 holds a semiconductor laser diode 101 by vacuum absorption or the like and moves the semiconductor laser diode 101 to over a region of the submount 131 to which the semiconductor laser diode 101 is mounted.

Next, as shown in FIG. 12B, after the solder material 132 has melted, the collet 137 holding the semiconductor laser diode 101 is lowered and then the semiconductor laser diode 101 is cooled down with being mounted on the solder material 132 on the submount 131. In this case, the semiconductor laser diode 101 is pressure-welded to the submount 131 with the collet 137 to sufficiently ensure a bonding area of the semiconductor laser 101 and the submount 131 with the solder material 132 interposed therebetween and to reduce the thickness of the solder material 132 to a very small level, thereby improving heat radiation characteristics.

Next, as shown in FIG. 12C, after the solder material 132 has completely coagulated, the collet 137 removes holding the semiconductor laser diode 101 by vacuum absorption and then the collet 137 is raised. With this operation, mounting is completed.

In the above-described process steps of the known mounting method, the semiconductor laser diode 101 and the submount 131 are completely bonded to each other at a temperature at which the solder material 132 is coagulated, and then while a temperature is dropped from the coagulation temperature to the room temperature, dimensions of each member are changed due to a difference between respective thermal expansion coefficients of the semiconductor laser diode 101 and the submount 131. At this time, distortion caused by the change in dimensions of each member is stored in the semiconductor laser diode 101.

When the distortion exists in a crystal of the semiconductor laser diode 101, a region in which a non-light-emitting recombination arises is formed, so that a so-called dark line defect (which will be hereinafter referred to as a “DLD”) is generated in energizing processes.

A DLD is a dislocation array which grows with a crystal defect and the like as a nucleus. Having grown to reach an active layer 113 of the semiconductor laser diode 101, the DLD becomes a light absorber. The DLD which has reached the active layer 113 causes an increase in a laser oscillation threshold and finally light emitting is stopped. That is, if a DLD exists, reduction in the reliability of the semiconductor laser diode 101 and deterioration of laser characteristics are caused.

Therefore, conventionally, measures to prevent as much as possible an increase in distortion in the semiconductor laser diode 101 caused by the difference between the respective thermal expansion coefficients of the submount 131 and the semiconductor laser diode 101 have been taken by using, as a material for the submount 131, Fe, Mo, SiC, AlN, or the like of which property values such as the thermal expansion coefficient and Young's modulus are close to those of a material for forming the semiconductor laser diode 101.

In recent years, however, with increase in the amount of an output of a semiconductor laser, a resonator length of a semiconductor laser diode has been increased, the size of a submount has been increased, and a junction area of the semiconductor laser diode and the submount with a solder material interposed therebetween has been increased. Accordingly, in bonding of the semiconductor laser diode and the submount with the solder material interposed therebetween, a flow resistance of the solder material is increased, so that force required for pressure welding is increased. Therefore, the semiconductor laser diode and the submount are bonded to each other with distortion generated therein. Thus, even after pressure welding by a collet has been removed, distortion due to the pressure welding tends to remain.

Moreover, the size of semiconductor lasers has been reduced and the integration density thereof has been increased. Therefore, it has become necessary to make the submount, which has been used only as a buffer material and a heat radiating member of a semiconductor laser diode in a known semiconductor laser, have other functions as a photoreceptor section and an IC circuit. Accordingly, Si or the like of which property values such as a thermal expansion coefficient and Young's modulus are different far from those of a material forming a semiconductor laser diode has become to be used as a material for the submount. Thus, distortion due to a difference between the respective thermal expansion coefficients of the semiconductor laser and the submount tends to increase.

Furthermore, to improve heat radiation characteristics of the semiconductor laser diode, in many cases, junction-down bonding in which a (principal) surface of the semiconductor laser diode closer to the active layer 13 is made to face downward (to the submount side) is performed in bonding the semiconductor laser diode to the submount.

However, in the semiconductor laser to which junction bonding has been performed, if a light emitting region and a bonding surface are close to each other, the light emitting region exists in part of the semiconductor laser diode which has a high residual stress. Therefore, reduction in laser characteristics and reliability is concerned furthermore.

To cope with the above-described problems relating to mounting of the semiconductor laser diode, as disclosed in Japanese Laid-Open Publication No. 2002-217480, a method in which after mounting, heating is again performed to re-melt a solder material and thereby ease distortion generated during mounting has been proposed.

Moreover, as a method for solving the problems by changing the structure of a semiconductor laser diode, as disclosed in Japanese Laid-Open Publication No. 7-193315, a method in which convexes and concaves are formed in a back surface of a semiconductor laser diode (which is more distant from an active region) to ease a crack or distortion generated due to a difference between the respective thermal expansion coefficients of the semiconductor laser diode and an assembly substrate has been proposed and also, as disclosed in Japanese Laid-Open Publication No. 2000-68591, a method in which a ridge part extending along a stripe on a principal surface of a semiconductor laser (which is more distant from an active layer) is lowered by providing a concave portion so as to be located lower than an upper surface of a contact layer to avoid a concentration of distortion has been proposed.

### SUMMARY OF THE INVENTION

However, distortion generated in a semiconductor laser diode is determined not only by respective dimensions, shapes and materials of the semiconductor laser diode, a submount and a collet, the pressure welding force of the collet and the like, but also by combined effects of a plurality of different factors. Therefore, a residual stress is locally generated and also bonding states of a solder material in mounting are largely influenced.

In an examination conducted by the present inventors, for example, as in Japanese Laid-Open Publication No. 2002-217480, re-heating is performed after mounting, so that improvements of an operating life, characteristics of the polarization ratio and the like can be observed. However, there has been no clear co-relation among the amount of change (the amount of curling) of the semiconductor laser diode after re-heating and the operating life and laser characteristics of the semiconductor laser. Therefore, the effect of easing distortion locally and irregularly between the semiconductor laser diode and the submount with a solder material interposed therebetween is considered as the main effect achieved by performing re-heating after mounting and the like.

Moreover, when the length of the resonator of the semiconductor laser diode is small, a curling after mounting is hardly generated but reduction in an operating life may be caused even in such a semiconductor laser. Moreover, not only with a ridge type semiconductor laser diode having a ridge on a surface thereof (closer to an active layer) but also with a recess type semiconductor laser diode which does not have a ridge, the operating life of the semiconductor laser may be reduced.

As a result of an analysis of such semiconductor lasers with a reduced operating life, many semiconductor lasers in which a solder material between the semiconductor laser diode and the submount does not spread enough and thus the thickness of a solder is not uniform or only a certain region is locally bonded were found.

When a solder material does not uniformly spread, a region firmly bonded and a region which is not bonded at all exist mixedly on the same surface of a semiconductor laser, so that irregular distortion remains in the diode.

Therefore, as a bonding condition of the semiconductor laser diode, a solder material spread thin and uniform. However, especially, in a high power semiconductor laser, as a bonding area of a semiconductor laser diode and a submount is increased, the flow resistance of a solder material is influenced in many cases. Specifically, in many cases, increase in the bonding area causes a bad flow of a solder material, so that the solder material spreads nonuniformly and an area at which the semiconductor laser and the submount are properly bonded is reduced. Moreover, pressure welding by the collet is increased in order to make the solder material uniformly spread, distortion of the semiconductor laser diode tends to remain. Moreover, if an excessive amount of a solder material is used to make the solder material uniformly spread, force required for pressure welding is increased and also a difference in the thickness of the solder material or bonding strength varies, thereby generating distortion.

Regardless of the shape and structure of the semiconductor laser diode, these inconveniences are caused due to variations in mounting conditions, an inclination of each member, and the like. To suppress the inconveniences, it is necessary to ensure productivity and to adjust mounting conditions more strictly. However, in bonding the semiconductor laser diode and the submount, it is very difficult to ensure the bonding area of the semiconductor laser and the submount while increasing the amount of the solder material and then expelling an unnecessary portion of the solder material to the outside of the semiconductor diode with low pressure welding force in order to achieve excellent heat radiation characteristics with a reduced thickness of the solder material to a very small level.

The above-described problem can not be solved even if any one of the methods described in the background of the invention is used. Specifically, in a method described in Japanese Laid-Open Publication No. 2002-217480, although distortion generated during mounting can be reduced, the solder material has to be completely melted again at a high temperature to completely eliminate causes for the generation of distortion by making the locally bonded solder material spread uniformly. In this case, the semiconductor laser diode is not held by the collet or the like and thus there is a concern that the semiconductor laser might be moved. Furthermore, after mounting has been performed, heat treatment and the like have to be performed again. Therefore, productivity is largely reduced.

Moreover, in a method described in Japanese Laid-Open Publication No. 7-193315, a chip crack or distortion due to a difference in thermal expansion coefficient can be eased, but the generation of nonuniform distortion of the solder material generated on a surface to be bonded can not be prevented.

Moreover, in a method described in Japanese Laid-Open Publication No. 2000-68591, although a ridge located in a bonding surface side of the semiconductor laser is etched to planarize the bonding surface, thereby suppressing a concentration of distortion to a ridge portion, non-uniform distortion of the solder material generated in a surface to be bonded can not be prevented.

In view of the above-described problems, the present invention has been devised. It is therefore an object of the present invention to provide a semiconductor laser in which, regardless of the respective sizes of a semiconductor laser diode and a submount, a material for and the amount of a solder and the level of pressure welding by a collet, reduction in the operating life due to distortion in the semiconductor laser diode and deterioration of laser characteristics are suppressed without reducing productivity.

To solve the above-described problem, a first semiconductor laser according to the present invention is a semiconductor laser capable of outputting laser light, comprising in an upper surface thereof a slit having a concave shape and extending from one end to the other end.

In this structure, the slit having a concave shape is provided in the upper surface of the semiconductor laser. Thus, when a semiconductor laser diode is junction-down mounted on a submount, an excessive solder material can be expelled in a simple manner, so that the solder material can be made to uniformly spread and have a small thickness at a bonding surface. Accordingly, application of nonuniform distortion to the semiconductor laser after mounting process can be prevented. Therefore, reduction in the operating life of the semiconductor laser and deterioration of laser characteristics thereof can be prevented.

If the semiconductor laser includes: a submount bonded to the upper surface; and a bonding material for bonding the submount to the upper surface, heat generated during an operation of the semiconductor laser can be efficiently released. Note that with the slit having a concave shape provided, distortion is not nonuniformly applied to the inside of the semiconductor laser. Therefore, reduction in the operating life of the semiconductor laser and deterioration of laser characteristics thereof can be prevented.

If the semiconductor laser includes: a substrate; a first clad layer of a first conductive type formed on a principal surface of the substrate; an active layer capable of outputting the laser light formed on the first clad layer; a second clad layer of a second conductive type formed on the active layer; a current blocking layer formed on the second clad layer; a third clad layer of the second conductive type formed on or over the second clad layer; a contact layer formed of semiconductor of the second conductive type on the third clad layer; and an ohmic electrode formed on or over the contact layer, the semiconductor laser can be made to function as an edge-emitting laser for irradiating laser light in the end face direction.

The slit may be formed so as to be located in the contact layer and the ohmic electrode.

Moreover, a stripe may be formed in the current blocking layer so as to extend in the direction in which the laser light is emitted, and the third clad layer may be formed so as to fill at least the stripe.

Alternatively, the semiconductor laser may have a structure in which the slit is provided in the contact layer and the ohmic electrode is not provided in the slit.

As another option, the semiconductor laser may have a structure in which the upper surface of the ohmic electrode is flat, and the semiconductor laser further includes a metal layer formed on the ohmic electrode having the slit provided therein.

If a peripheral portion of the metal layer is removed, in performing cleaving to obtain a chip form, processing can be facilitated.

The semiconductor laser may further include a semiconductor layer formed so as to be located on the contact layer and under the ohmic electrode.

If the depth of the slit is smaller than the thickness of the contact layer, the slit does not influence light emission at the active layer.

If the slit is provided so as to cross the stripe when two-dimensionally viewed, an excessive solder is prevented from shielding a light emitting point. In that case, the amount of the solder can be increased to stabilize bonding.

If the slit is provided so as to cross the stripe at a center portion of the stripe in the long side direction when two-dimensionally viewed, a semiconductor laser diode is bonded to the submount with support at two points. Thus, an inclination of the semiconductor laser, except for the submount, can be prevented. Moreover, distortion received from the solder can be made uniform and therefore the semiconductor laser of the present invention is preferable.

If the slit is provided so as to be parallel to the stripe and so as not to overlap with the stripe when two-dimensionally viewed, an excessive solder is prevented from shielding a light emitting point.

If the slit is provided plural in number, an excessive solder in a larger amount can be expelled out and therefore the semiconductor laser of the present invention is preferable. Moreover, a semiconductor laser diode can be stably bonded to the submount in mounting process and the effect of making distortion uniform can be achieved.

Note that with the above-described structure, not only variations in quality of the semiconductor laser can be minimized, but also stable quality of the semiconductor laser with respect to the temperature of an environment where the semiconductor laser is used can be maintained. Moreover, there is no need for strictly controlling assembly conditions, so that the number of man-hours for control and the number of process steps can be reduced. Then, since there is no need for strictly controlling assembly conditions, the level of a specification for an assembly apparatus can be lowered, so that the effect of reducing device costs for apparatuses can be achieved.

A first method for fabricating a semiconductor laser according to the present invention is a method for fabricating a semiconductor laser including a first clad layer of a first conductive type formed on a principal surface of a substrate, an active layer capable of outputting the laser light formed on the first clad layer, a second clad layer of a second conductive type formed on the active layer, a current blocking layer formed on the second clad layer, a third clad layer of the second conductive type formed on or over the second clad layer, a contact layer formed of semiconductor of the second conductive type on the third clad layer, and an ohmic electrode formed on or over the contact layer, the method comprising the steps of: a) forming, on the third clad layer, the contact layer including a slit having a concave shape and extending from one end to the other end; and b) forming the ohmic electrode on the contact layer.

According to this method, when a semiconductor laser is mounted on a submount, a slit for reducing distortion applied from a bonding member can be formed.

If the method further includes after the step b), the step of bonding an upper surface of the ohmic electrode and a submount with each other using a bonding member, a semiconductor laser in which distortion applied to the inside of the semiconductor laser generated in the process of bonding the submount is reduced, which has a long operating life and of which performance is less deteriorated can be fabricated.

If the step a) includes the step of depositing semiconductor over the third clad layer to form a first semiconductor layer, the step of forming on the first semiconductor layer a resist having an opening, and the step of performing wet etching or dry etching using the resist as a mask to form the slit, a slit can be formed in a simple manner.

A second method for fabricating a semiconductor laser according to the present invention is a method for fabricating a semiconductor laser including a first clad layer of a first conductive type formed on a principal surface of a substrate, an active layer capable of outputting the laser light formed on the first clad layer, a second clad layer of a second conductive type formed on the active layer, a current blocking layer formed on the second clad layer, a third clad layer of the second conductive type formed on or over the second clad layer, a contact layer formed of semiconductor of the second conductive type on the third clad layer, a second semiconductor layer formed on the contact layer, and an ohmic electrode formed on the second semiconductor layer, the method comprising the step of: c) forming on the contact layer the second semiconductor layer including a slit having a concave shape and extending from one end to the other end.

According to this method, a semiconductor laser in which distortion applied from a solder during mounting process is made uniform can be also fabricated. Specifically, according to this method, even if the thickness of a contact layer is small, a slit can be provided in a semiconductor laser.

The step c) may include the step of covering the contact layer with a protection film and then removing the protection film so as to leave part of the protection film located in a region in which a slit is formed, the step of depositing semiconductor over the contact layer to form the second semiconductor layer, and the step of removing part of the protection film.

A third method for fabricating a semiconductor laser according to the present invention is a method for fabricating a semiconductor laser including a first clad layer of a first conductive type formed on a principal surface of a substrate, an active layer capable of outputting the laser light formed on the first clad layer, a second clad layer of a second conductive type formed on the active layer, a current blocking layer formed on the second clad layer, a third clad layer of the second conductive type formed on or over the second clad layer, a contact layer formed of semiconductor of the second conductive type on the third clad layer, and an ohmic electrode formed on or over the contact layer, the method comprising the steps of: d) forming the ohmic electrode so as to have a flat upper surface, and e) forming on the ohmic electrode a metal layer including a slit having a concave shape and extending from one end to the other end.

According to this method, a semiconductor laser of which performance is not deteriorated after mounding to a submount and in which an inconvenience such as curling of a laser chip is not caused can be fabricated. Specifically, according to this method, even if the thickness of the contact layer is small, a slit can be also provided to a semiconductor laser.

If in the step e), the metal layer is formed using plating, the metal layer can be formed in a simple manner. Therefore, this method is preferable.

### BRIEF DESCRIPTION OF THE DRAWINGS

FIG. 1 is a perspective view illustrating a mounting surface of a semiconductor laser according to a first embodiment of the present invention.

FIG. 2 is an external view illustrating the semiconductor laser of the first embodiment of the present invention.

FIG. 3A is a view schematically illustrating a submount in the semiconductor laser of the first embodiment of the present invention after the semiconductor laser bonded to the submount with the solder material interposed therebetween have been removed; FIG. 3B is a view schematically illustrating a submount in the known semiconductor laser after the semiconductor laser bonded to the submount with the solder material interposed therebetween have been removed.

FIG. 4A is a block diagram illustrating cross-sections taken along the line X-X′ of FIG. 2 when the semiconductor laser of the first embodiment is bonded to a submount; and FIG. 4B is a block diagram illustrating cross-sections taken along the line X-X′ of FIG. 2 when the known semiconductor laser is bonded to a submount.

FIG. 5 is a graph showing comparison of characteristics of the polarization ratio between the semiconductor laser of the first embodiment of the present invention and the known semiconductor laser.

FIG. 6 is a graph showing comparison of results of a reliability test between the semiconductor laser of the first embodiment of the present invention and the known semiconductor laser.

FIGS. 7A and 7B are top and cross-sectional views schematically illustrating a semiconductor laser of a second embodiment of the present invention.

FIG. 8 illustrates plan views of several slit structures for a semiconductor laser according to a third embodiment of the present invention.

FIG. 9 is a perspective view illustrating a mounting surface of a semiconductor laser according to a fourth embodiment of the present invention.

FIG. 10A is a perspective view illustrating a mounting surface of a semiconductor laser formed using a first method according to a fifth embodiment of the present invention; and FIG. 10B is a perspective view illustrating a mounting surface of a semiconductor laser formed using a second method according to the fifth embodiment of the present invention.

FIG. 11 is a view schematically illustrating a mask for simultaneously forming a slit and an isolation trench used in fabricating the semiconductor laser of the first embodiment.

FIGS. 12A through 12C are cross-sectional views illustrating respective steps for mounting for the known semiconductor laser.

### DESCRIPTION OF THE PREFERRED EMBODIMENTS

Hereinafter, embodiments of a semiconductor laser according to the present invention will be described with reference to the accompanying drawings.

### First Embodiment

Structure of Semiconductor Laser

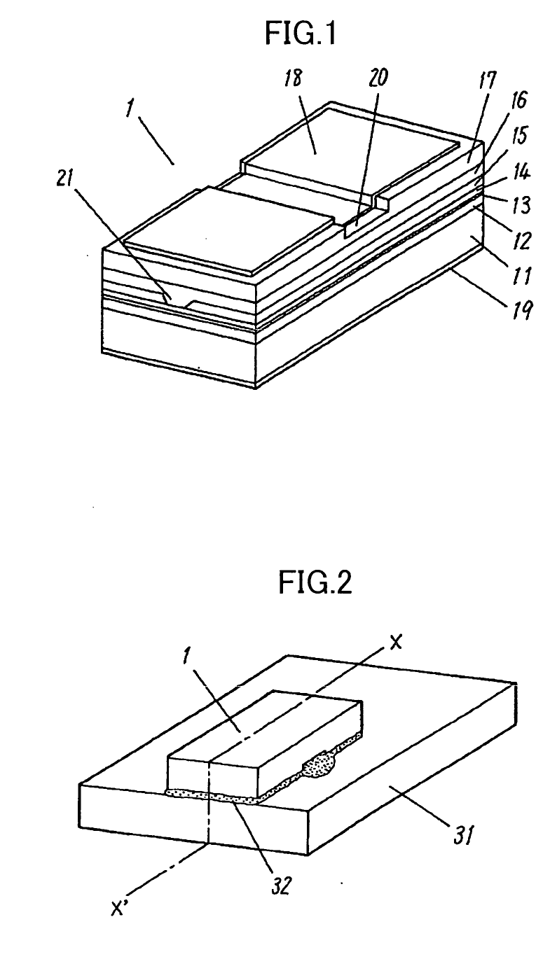

FIG. 1 is a perspective view illustrating a mounting surface of a semiconductor laser according to a first embodiment of the present invention.

A semiconductor laser 1 includes an n-type semiconductor substrate 11, an n-type clad layer 12, an active layer 13, a p-type first clad layer 14, a current blocking layer 15, a p-type second clad layer 16 and a p-type contact layer 17. The n-type clad layer 12, the active layer 13, the p-type first clad layer 14, the current blocking layer 15, the p-type second clad layer 16 and the p-type contact layer 17 are stacked in this order on a principal surface of the n-type semiconductor substrate 11. Moreover, a p-side ohmic electrode 18 is provided on the p-type contact layer 17 and an n-side ohmic electrode 19 is formed on a back surface of the n-type semiconductor substrate 11.

In this embodiment, a material for and the thickness of each semiconductor layer are set as follows.

(1) The n-type semiconductor layer 11 is formed of GaAs or the like so as to have a thickness of, e.g., 90-110 μm.

(2) The n-type clad layer 12 is formed of AlGaAs, AlGaInP or the like so as to have a thickness of, e.g., 1-2 μm.

(3) The active layer 13 is formed of GaAs, AlGaAs, InGaP or the like so as to have a thickness of, e.g., 0.01 μm, or may be formed of a plurality of lamination bodies with different compositions (which will be hereinafter referred to as a “quantum well”). An oscillation wave length is determined mainly by an energy gap of semiconductor forming the active layer. GaAs or AlGaAs is mainly used for semiconductor laser in the 780 nm wavelength band for use in optical pickup for CDs and InGaP is mainly used for semiconductor laser in the 650 nm wavelength band for use in optical pickup for DVDs.

(4) The p-type first clad layer 14 is formed of AlGaAs, AlGaInP or the like so as to have a thickness of, e.g., 0.1-0.2 μm.

(5) The current blocking layer 15 is formed of n-type GaAs, n-type AlGaAs, n-type AlInP or the like so as to have a thickness of, e.g., 0.5-1 μm.

(6) The p-type second clad layer 16 is formed of AlGaAs, AlGaInP or the like so as to have a thickness of, e.g., 2-3 μm in part in which a stripe is not located. Part thereof in which a stripe (i.e., an opening 21) is located will be described later.

(7) The p-type contact layer 17 is formed of GaAs or the like so as to have a thickness of, e.g., 2-3 μm in part in which a stripe is not located.

In the semiconductor laser of this embodiment, of side faces (with the principal and back surfaces assumed to be upper and lower surfaces, respectively), two end faces each having a width corresponding to the shorter side direction of the laser diode and facing each other forms an optical resonator and serve as light emitting surfaces. In the current blocking layer 15, an opening is provided so as to have a long and narrow stripe shape and extend in the light resonator direction (i.e., in the longer side direction of the principal surface of the semiconductor laser or the light emitting direction). A current injected via the p-side ohmic electrode 18 and the n-side ohmic electrode 19 flows into the active layer 13 through the opening, so that laser oscillation occurs. The opening is, in general, referred so as a “stripe” and therefore the opening provided in the current blocking layer 15 will be hereinafter referred to as a stripe 21.

FIG. 2 is an external view illustrating the semiconductor laser of the first embodiment mounted on a submount. As shown in FIG. 2, when the semiconductor laser 1 is mounted on an Si submount 31, the p-side ohmic electrode 18 is made to face the submount 31 and bonded thereto using a solder material 32.

The present inventors confirmed that when the p-side ohmic electrode 18 side of the semiconductor laser 1 is bonded onto the Si submount 31, a better operating life and better characteristics of the polarization ratio than those in a known structure which does not include a concave portion can be achieved. The effects and characteristics of the semiconductor laser of this embodiment will be described later.

Characteristics of Semiconductor Laser

A characteristic of the semiconductor laser diode of this embodiment is that a slit 20 is formed in a center portion of the p-type contact layer 17 in the optical resonator direction (i.e., in the longer side direction of the principal surface of the semiconductor laser or the laser light emitting direction) so as to have a concave shape and intersect with the stripe 21 when viewed from the top and, to follow the slit 20, a concave portion is formed in the p-side ohmic electrode 18 provided on the p-type contact layer 17. Specifically, in an example shown in FIG. 1, the stripe 21 and the slit 20 intersect with each other at right angles when viewed from the top.

The thickness of part of the p-type contact layer 17 in which the slit 20 is not located is 3 μm and the depth of the slit 20 is 1.5 μm. The slit 20 preferably has a depth at which the slit 20 does not break through the p-type contact layer 17. If the slit 20, which intersects with the stripe 21 at right angles, breaks through the p-type contact layer 17, laser characteristics are influenced.

Moreover, when the p-type contact layer is too thick, a concern about deterioration of temperature characteristics of the semiconductor laser arises. Therefore, the thickness of the p-type contact layer is preferably 5 μm or less.

Method for Fabricating Semiconductor Laser

Hereinafter, a method for fabricating the semiconductor laser 1 of this embodiment will be described.

First, an n-type clad layer 12, an active layer 13, a p-type first clad layer 14, and a current blocking layer 15 are grown in this order on a principal surface of an n-type semiconductor substrate 11. Next, a resist pattern (not shown) is formed so as to have a stripe shape by photolithography and then the current blocking layer 15 is etched, thereby forming a stripe 21. Subsequently, the resist is removed and then a p-type second clad layer 16 and a p-type contact layer 17 are grown in this order. The layers are grown by, e.g., metal organic chemical vapor deposition.

Thereafter, a slit 20 is formed in a predetermined position in the p-type contact layer 17. A method for forming the slit 20 is performed in the following manner.

First, a positive resist is applied to an entire upper surface of a semiconductor lamination body of which the uppermost surface is the p-type contact layer 17 and then the resist is hardened. Herein, the semiconductor lamination body means to be the semiconductor layers as a whole stacked on the principal surface of the n-type semiconductor substrate 11.

Next, only part of the resist located on a region of the semiconductor lamination body to be the slit 20 is selectively removed by photolithography using a mask having an opening with a shape corresponding to the slit 20 crossing the stripe 21 almost at a center of the stripe 21 when viewed from the top. Thereafter, only part of the p-type contact layer 17 which is not covered by the resist is removed by wet etching. In this case, the p-type contact layer 17 is formed of GaAs having a thickness of 3 μm and a mixture of tartaric acid and a hydrogen peroxide solution is used as an etchant. Moreover, an etching time is adjusted so that the slit 20 does not break through the contact layer. Thus, the slit 20 of a depth of 1.5 μm is obtained. Thereafter, a resist film is removed.

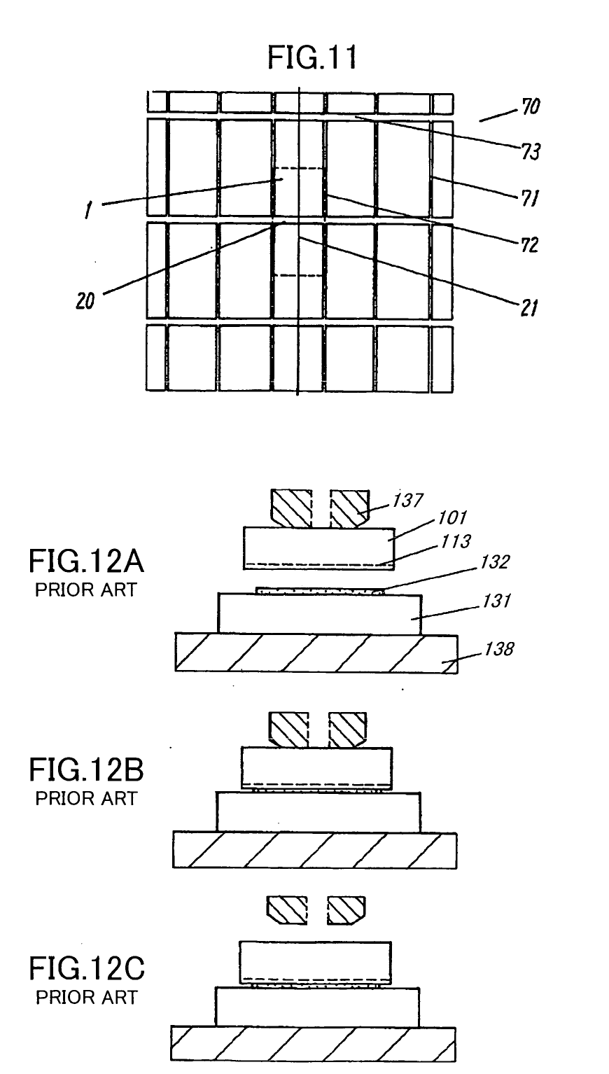

Note that the slit 20 is formed using wet etching in this embodiment. However, some other known method such as dry etching may be used. In that case, another resist pattern having a stripe-shaped opening 71 (see FIG. 11) is formed in the direction in which the resist crosses the stripe 21 and then the p-type contact layer 17 is etched to form a slit 20 by a known method such as wet etching and dry etching so that the slit 20 does not reach the p-type second clad layer 16.

Moreover, simultaneously with forming the slit 20, an isolation trench 73 (see FIG. 11) for dividing the semiconductor laser into individual device in the subsequent process step may be formed. In this case, FIG. 11 is a view schematically illustrating a mask used for simultaneously forming the slit and the isolation trench of the first embodiment.

As shown in FIG. 11, photolithography is performed using the mask 70 having the opening 71 for forming the slit 20 and an opening 72 provided in each interval corresponding to a semiconductor laser so as to intersect with the slit 20 at right angles and have a width of about 1 μm, thereby simultaneously forming a resist pattern including the openings 71 and 72. Then, wet etching, dry etching or some other known technique is performed to simultaneously form the slit 20 and the isolation trench 73 intersecting with the slit 20 at right angles and having the same depth as that of the slit 20. Thus, it becomes possible to simultaneously form the slit 20 and the isolation trench 73 without adding another process step of photolithography.

Thereafter, a conduction film is formed on a predetermined location in the p-type contact layer 17 by sputtering or the like and then a p-side ohmic electrode 18 is formed on the principal surface of the p-type contact layer 17 by known lithography and etching. The p-side ohmic electrode 18 has, for example, a lamination structure in which Cr with a thickness of 50 nm, Pt with a thickness of 100 nm and Au with a thickness of 800 mm are stacked in this order from the closer side to the p-type contact layer. Au as the uppermost surface may be formed in a pattern shape. In this case, the “pattern shape” is a shape in which a periphery portion of the p-type ohmic electrode 18 is removed with respect to the outside shape of the principal surface of the p-type contact layer 17. Moreover, an Au plating layer with a thickness of about 1-3 μm may be formed on Au.

Thereafter, the semiconductor lamination body is cleaved at regular intervals according to a semiconductor laser resonator length (i.e., width of the semiconductor laser in the longer side direction) so as to have a bar-like shape, thereby forming an end face to be a resonator mirror surface. Furthermore, a desired end face coating film for preventing oxidization of end faces and controlling reflectance is formed.

Thereafter, the semiconductor lamination body having a bar-like shape is divided into individual semiconductor lasers. Thus, the semiconductor laser of this embodiment can be obtained.

The semiconductor laser 1 formed in the above-described manner is held by a collet with a surface on which the p-side ohmic electrode 18 is formed facing downward and is placed at a predetermined location on the submount 31.

Thereafter, each of the semiconductor laser 1 and the submount 31 or only the submount 31 is heated so that the solder material 32 is softened. Thereafter, the solder material 32 is cooled by natural cooling or forced cooling to harden the solder material and then bonding process is completed. At this time, the semiconductor laser 1 is kept being pressed to the submount 31 by the collet until the solder material 32 is hardened and the semiconductor laser is fixed at a certain location.

Note that in the boding process of the semiconductor laser 1 with the submount 31, a solder layer for bonding with the submount 31 may be formed on an upper surface of the p-side ohmic electrode 18 in advance. In that case, the area of the solder layer can be made smaller than that of the semiconductor laser and the positional relationship between the submount 31 and the semiconductor laser is kept constant. Therefore, regardless of variations in location accuracy during mounting, the semiconductor laser and the submount can be bonded to each other more uniformly.

Moreover, a solder layer may be formed on the submount 31 in advance. However, depending on variations in mounting location accuracy between the semiconductor laser and the submount, a location shift may be caused in each of the semiconductor laser and the submount, so that nonuniform distortion may be generated. Therefore, a close attention is required.

Moreover, as a solder material, PbSn, AuSi, AuGe, AuZe, InSb and the like may be used, in addition to AuSn.

Slit and its Effects

Effects of a slit when the semiconductor laser 1 having the above-described shape is junction-down mounted on the submount will be described.

As shown in FIG. 2, when the semiconductor laser 1 is bonded to the submount 31 using the solder material 32 with the p-side ohmic electrode 18 and the submount 31 facing each other, in general, a solder layer is formed in advance over an upper surface of the submount 31 by plating or some other method.

The solder layer is formed to have the same size as the size of a laser chip in many cases. However, there are cases where the solder layer is formed to have a larger size than the size of the semiconductor laser and where the solder layer is formed over the entire upper surface of the submount 31. In general, the thickness of the solder layer is made to be 2-3 μm.

In this case, if the thickness of the solder layer is too small, a solder does not spread over an entire surface of the p-side ohmic electrode 18 of the semiconductor laser 1, so that insufficient bonding strength, deterioration of heat expansion properties and nonuniform distortion are caused. These become causes for reduction in the characteristics of the polarization ratio and the operating life of the semiconductor laser.

Therefore, to make the solder and the electrode wet enough, it is more preferable that the solder layer has a larger thickness. However, if the solder layer is too thick, an excessive solder irregularly flows to the outside of the semiconductor laser to become a solder ball. Accordingly, a light emitting point might be shielded or a short-circuiting fault might be caused. Moreover, the thickness of the solder which has not flowed to the outside of the semiconductor laser becomes nonuniform between the laser chip and the submount, so that nonuniform distortion is applied to the semiconductor laser. Thus, reduction in polarization ratio and deterioration of reliability are caused.

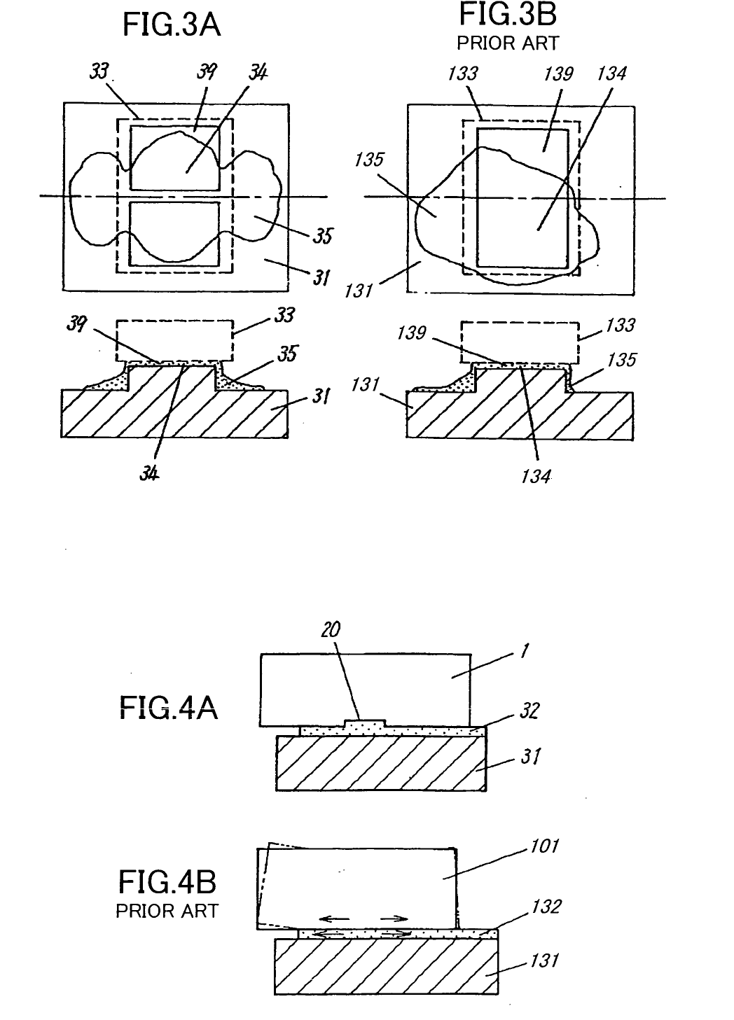

FIGS. 3A and 3B are views each schematically illustrating the submount after the semiconductor laser bonded to the submount with the solder material interposed therebetween has been removed in the semiconductor laser of the first embodiment of the present invention or the known semiconductor laser. FIG. 3A illustrates the semiconductor laser of this embodiment in which a slit is formed. FIG. 3B illustrates the known semiconductor laser in which a slit is not formed. In FIGS. 3A and 3B, rectangular regions 33 and 133 surrounded by dashed lines indicate the respective outside shapes of the semiconductor lasers. Each of the reference numerals 34 and 134 denotes a solder material on a bonding surface and each of the reference numerals 35 and 135 denotes an excessive solder material expelled to the outside of the semiconductor laser.

As shown in FIG. 3A, when a slit exists in the semiconductor laser, the solder material 34 uniformly spread over an entire bonding surface. Moreover, a slit portion is filled with the solder material 34. The excessive solder material 35 is expelled out from each side of the semiconductor laser in a substantially uniform manner.

In contrast, when a slit is not formed in the semiconductor laser of FIG. 3B, the solder material 134 nonuniformly spread over a bonding surface. Thus, variations in the thickness of the solder material and also a region firmly bonded or a region which is not bonded at all mixedly exist. Moreover, with the nonuniform spread of the solder material 134, the excessive solder 135 is irregularly expelled to the outside of the semiconductor laser. Furthermore, the amount of the expelled solder material is less than that in the case where a slit is provided and the thickness of the solder material on the bonding surface is large.

FIGS. 4A and 4B are cross-sectional views each taken along the line X-X′ of FIG. 2 in the semiconductor laser of this embodiment or the known semiconductor laser is bonded onto the submount. FIG. 4A illustrates the semiconductor laser of this embodiment in which the slit 20 is formed. FIG. 4B illustrates the known semiconductor laser in which a slit is not formed.

In general, since respective thermal expansion coefficients of a laser chip (semiconductor laser), a submount and a solder are different, distortion is generated in the laser chip due to a temperature difference between a temperature (250° C. to 350° C.) at which the solder is melted when bonding the laser chip and the room temperature.

Assume that Si is used for the submount. In the known semiconductor laser, since the thermal expansion coefficient of GaAs (6.9×10⁻⁶/K) is smaller than the thermal expansion coefficient of Si (2.6×10⁻⁶/K), tensile distortion is generated in a bonding surface between the semiconductor laser and the submount, as shown in FIG. 4B. In general, if a stress due to the tensile distortion exceeds 10⁸ Pa/cm² (=10⁹ dyn/cm²), a dislocation occurs in GaAs crystal. This causes deterioration of a semiconductor laser.

On the other hand, in the semiconductor laser of this embodiment, the slit 20 is provided in the center of the laser chip. Therefore, tensile distortion generated in the bonding surface is largely eased.

This is because in mounting process, the slit 20 is filled with a solder and Sn as a main component of the solder has an about ten times larger thermal expansion coefficient than that of Si, so that a slit portion is shrunk when cooled down from the temperature at which bonding is performed. Therefore, tensile distortion applied to the laser chip is eased.

Note that the depth of the slit is preferably a depth at which the slit does not break through the contact layer, as has been described, and the width of the slit is preferably about 3-20% of the optical resonator length (the length of the semiconductor laser of FIG. 1 in the light emitting direction).

As in this embodiment, with the slit structure provided in the semiconductor layer, the solder can be uniformly expelled to the outside of the semiconductor laser through the slit in a simple manner. Thus, even if the amount of the solder material is excessive, the thickness of the solder material can be made sufficiently thin without increasing the pressure welding force of the collet, so that uniform bonding can be achieved. Therefore, compared to the known semiconductor laser, curling of the laser chip due to the pressure welding force can be reduced. Moreover, if the slit is provided so as to cross the stripe at the substantially center of the stripe (i.e., a center portion of the stripe in the longer side direction), the effect of making distortion uniform can be achieved.

Specifically, in a high-power semiconductor laser having a large bonding area, the above-described effect can be markedly obtained. Moreover, the solder material is made to be expelled out in the right-left direction of the resonator. Thus, even if the amount of the solder material is excessive, it is possible to prevent a light emitting point of the resonator end face from being shielded by the expelled solder. Furthermore, the solder is expelled to certain locations and thus short-circuiting fault and the like can be improved, resulting in improvement of yield. Even if the slit 20 extends in the same direction as the direction in which the stripe 21 extends, the effect of reducing distortion applied to the laser chip can be also achieved.

Note that in this embodiment, the case in which the semiconductor laser is an edge emitting laser has been described. However, even in the case where the slit structure is provided in a surface emitting laser for emitting laser light to an upper portion of the active layer, distortion received from the solder can be uniformed and thus the same effects as those of the semiconductor laser of this embodiment can be expected.

Characteristics of Semiconductor Laser of the Present Invention

The present inventors formed a semiconductor laser having the structure of FIG. 1 and an optical resonator length of 800 μm, a laser chip width of 300 μm and a slit width of 40 μm and conducted a comparative experiment with a semiconductor laser having a structure in which a slit is not formed.

Hereinafter, data for the polarization ratio and reliability which have been obtained by the comparative experiment will be shown.

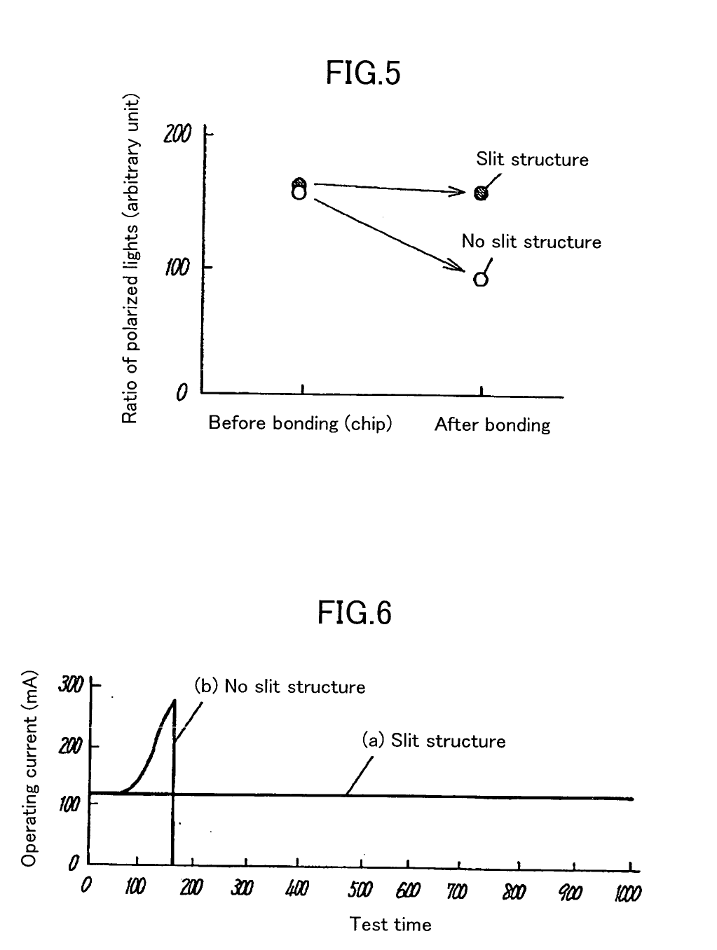

FIG. 5 is a graph showing comparison of characteristics of the polarization ratio between the semiconductor laser of the first embodiment of the present invention and the known semiconductor laser.

In the semiconductor laser, an electric field is, in general, linear-polarized in the parallel direction to an active layer. However, if there is distortion in a laser chip, birefringence due to the distortion appears, so that characteristics of the polarization ratio are deteriorated. Note that the polarization ratio is expressed by the ratio (TE/TM) between polarized components (TE) in the parallel direction to the active layer and polarized components (TM) in the vertical direction to the active layer, and shows that the larger the ratio is, the more excellent the semiconductor laser is.

As shown in FIG. 5, for the polarization ratio in the structure of this embodiment in which a slit is formed, measurement results obtained in the semiconductor diode itself are the substantially the same as measurement values obtained after the semiconductor laser diode has been bonded to the submount. In contrast, the polarization ratio after mounting process becomes smaller than that before the mounting process in the known structure in which a slit is not provided.

From these results, it was confirmed that with the structure including a slit, distortion caused by bonding is reduced.

FIG. 6 is a graph showing comparison of results of a reliability test between the semiconductor laser of the first embodiment of the present invention and the known semiconductor laser. In FIG. 6, a graph (a) indicates characteristics of the semiconductor laser of the present invention in which a slit is provided and a graph (b) indicates characteristics of the known semiconductor laser in which a slit is not provided. In this test, a current for energizing the semiconductor laser was controlled so that an optical output of each of the semiconductor lasers becomes constant and examined change with time in current values when each of the semiconductor lasers was continuously operated. Note that an upper limit of a test time was set to be 1000 hours and energizing is stopped after 1000 hours elapsed. The measurement results were obtained from a plurality of semiconductor lasers for each of the inventive and known semiconductor lasers.

Increase in current values for obtaining a constant optical output shows that a semiconductor laser is deteriorated. Thus, it is possible to estimate a life of a semiconductor laser from a time for energizing the semiconductor laser until the current value is increased so much that a constant optical output can not be maintained.

In general, as the temperature of a semiconductor laser is increased, the life of the semiconductor laser is reduced. When the temperature increased by 10° C., the life is reduced to about half. In this comparison experiment, the temperature of each semiconductor laser was increased to accelerate deterioration of the semiconductor laser. In this manner, the life of each semiconductor laser was examined in a short time.

As shown in FIG. 6, among semiconductor lasers having the known structure in which a slit was not provided, when a several tens hours elapsed, laser diodes with an increased current value started appeared. However, among semiconductor lasers having the structure of the present invention in which a slit was provided, there was no laser diode with an increased current value until 1000 hours elapsed. From the results, it can be seen that with the slit provided, distortion received by the solder is reduced, so that the life of the semiconductor laser is increased and the operating reliability is improved.

Moreover, the effect of improving characteristics can be achieved not only in a high-power semiconductor laser having a great resonator length but also in a low-power semiconductor laser having a small resonator length.

For example, in an infrared, low-power output semiconductor laser having a resonator length of 200 μm and a width of 160 μm, di-bonding is performed at an increased speed. At this time, to reduce time required for mounting, a hating time and a time for pressure welding by a collet are reduced, thereby increasing in variations in mounting.

In such a case, it was also confirmed that with the slit structure provided, spread of a solder material could be stabilized, distortion could be reduced, characteristics of the polarization ratio could be improved before and after mounting, and initial defects in the operating life test could be largely reduced.

As has been described, by providing the slit intersecting with the stripe with right angles in a contact layer, a flow of the solder in junction-down mounting can be controlled to uniform or reduce distortion applied to the laser chip from the excessive solder. Therefore, characteristics of the polarization ratio of the semiconductor laser and reliability thereof can be improved.

Note that in the semiconductor laser of FIG. 1, the p-side ohmic electrode 18 is formed also in the slit 20. However, the present inventors confirmed that the same effects could be achieved with a structure in which an electrode is not formed in a slit or a structure in which an ohmic electrode does not have an Au layer and is formed of Cr/Pt.

Specifically, in the slit, a barrier layer of Pt, Ti, Ni or the like is preferably formed to prevent diffusion of a solder material to the inside of a semiconductor laser. This is because Sn usually used as a solder material in many cases is thermally diffused in the semiconductor laser to form an impurity level, so that deterioration of a laser output prevented.

Moreover, assume that the uppermost surface of the p-side ohmic electrode 18 in the slit is Au. Even if the size of a semiconductor laser to be used is small, a bonding strength and a thermal expansion area can be ensured. On the other hand, when the size of a semiconductor laser to be used is large and a bonding strength and a thermal expansion are sufficiently large, the uppermost surface of the p-side ohmic electrode in the slit may be some other than Au. In that case, the uppermost surface of the p-side ohmic electrode in the slit and a solder material do not form an alloy. Therefore, the excessive solder can be expelled to the outside of the semiconductor laser in a more simple manner.

Note that in this embodiment, the example in which the p-type ohmic electrode side is bonded to the submount has been described. However, there may be cases in which an n-side ohmic electrode side is bonded to the submount.

### Second Embodiment

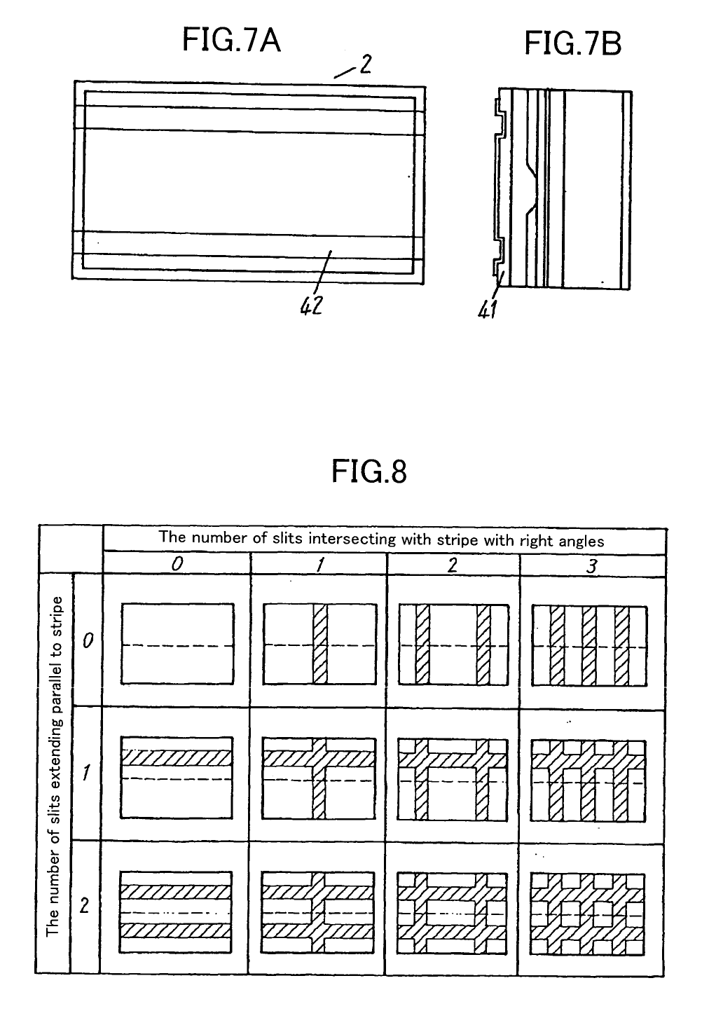

FIGS. 7A and 7B are views schematically illustrating a semiconductor laser 2 according to a second embodiment of the present invention. FIG. 7A is a top view of the semiconductor laser 2. FIG. 7B is a cross-sectional view of the semiconductor laser 2. The semiconductor laser of this embodiment differs from the semiconductor laser of the first embodiment in that a slit 42 provided in a p-type contact layer 41 extends in the parallel direction to a stripe and the slit 42 is formed so as not to be located directly over the stripe. Therefore, the stripe and the slit 42 do not overlap each other when viewed from the top.

In the semiconductor laser of this embodiment, as in the first embodiment, a solder can be easily expelled to the outside of the semiconductor laser through the slit 42. Therefore, even if the amount of a solder material is excessive, the thickness of the solder material can be sufficiently small and a semiconductor laser diode can be uniformly bonded to a submount without increasing pressure welding force of a collet. Accordingly, compared to the known structure, curling of a laser chip due to pressure welding by the collet can be reduced.

Moreover, particularly in a high-power semiconductor laser with a large bonding area, the above-described effect can be noticeably achieved.

Moreover, as shown in FIG. 7A, in this embodiment, the example in which two slits are formed so as to be symmetric about the stripe has been described. Although it is also possible to achieve the above-described effect even when only one slit is provided in one of the sides, with the slits 42 provided at the both sides of the stripe, the laser chip can be more stably bonded. Therefore, providing the slits 42 on the both side of the stripe, respectively, is effective in making distortion uniform.

Moreover, the reason why the slit is provided so as to be located directly over the stripe is to prevent a light emitting point of a resonator end face from being shielded by a solder which has flowed out of a bonding surface.

Moreover, the structure of the semiconductor laser of this embodiment is preferably applied to the case where the thickness of the contact layer is small or a surface level difference made by a stripe potion is large. In such a structure, if a slit is formed so as to cross a stripe, damages to the stripe portion by the process of forming the slit are concerned.

By applying the structure of this embodiment to such a semiconductor laser, the stripe portion is not damaged and also an excessive solder material is expelled to a location distant from the stripe. Thus, bonding can be uniformly performed.

Note that the depth of the slit is preferably a depth at which the slit does not break through the contact layer and the width of the slit is more preferably about 3-50% of the semiconductor laser. When the width of the slit exceeds 50% of the width of the semiconductor laser, a bonding area with the submount is reduced, so that bonding strength might be reduced. However, the effect of making distortion received from the solder uniform is not influenced by the width of the slit.

### Third Embodiment

FIG. 8 illustrates plan views of several slit structures for a semiconductor laser according to a third embodiment of the present invention.

In the first embodiment, the structure having a slit intersecting with a stripe at right angles has been described. In second embodiment, the structure having two slits each extending in parallel to a stripe has been described.

In this embodiment, the structure having a plurality of slits each extending so as to intersect with a stripe at right angle or extending in the parallel direction to a stripe when two-dimensionally viewed and, furthermore, the structure having slits one of which extends so as to intersect with a stripe at right angles and the other of which extends in the parallel direction to the stripe are described.

In the semiconductor laser of this embodiment, distortion applied to a laser chip can be made to be uniform and also an excessive solder material can be expelled to the outside of the semiconductor laser by increasing the number of slits. Therefore, deterioration of the performance of the semiconductor laser can be more effectively prevented than the first and second embodiments.

However, an area of an upper surface of a p-type contact layer serving as a bonding surface with a submount is reduced according to the increase of the number of slits. Accordingly, if a total area of slit portions is too large, reduction in the bonding strength of the semiconductor laser and deterioration of heat radiation characteristics are concerned. Therefore, it is necessary to carefully choose an optimal structure in view of properties and reliability. As a standard, the total of widths of the plurality of slits may be 50% or less of the width of the semiconductor laser.

### Fourth Embodiment

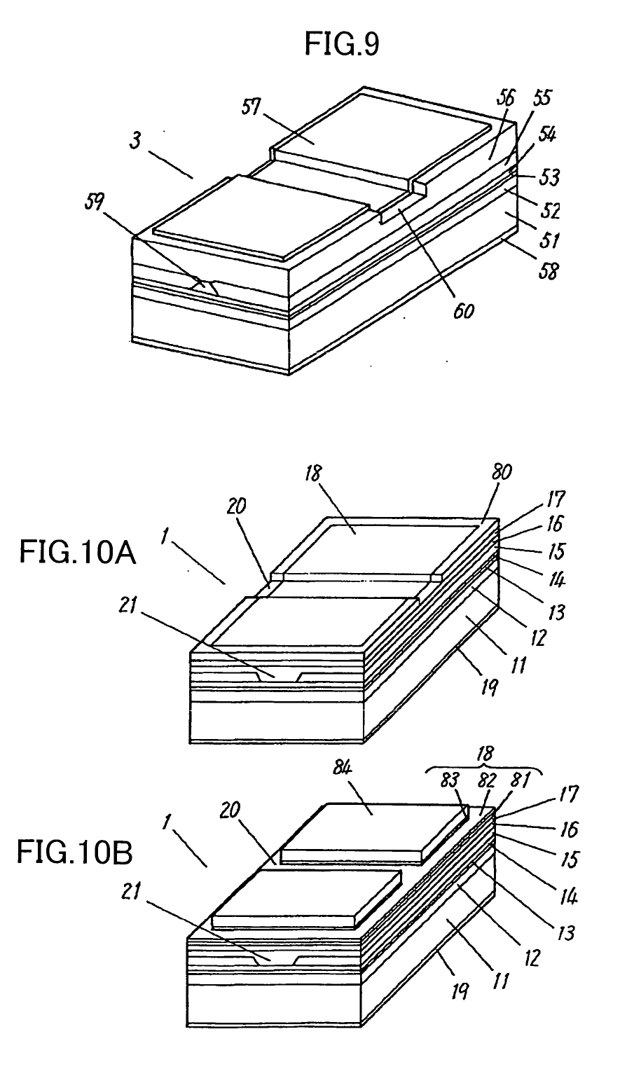

FIG. 9 is a perspective view illustrating a mounting surface of a semiconductor laser according to a fourth embodiment of the present invention.

A semiconductor laser 3 includes an n-type semiconductor substrate 51, an n-type clad layer 52, an active layer 53, a p-type first clad layer 54, a current blocking layer 55, a p-type second clad (ridge) layer 59 and a p-type contact layer 56. The n-type clad layer 52, the active layer 53, the p-type first clad layer 54, the current blocking layer 55, the p-type second clad layer 59 and the p-type contact layer 56 are stacked in this order on a principal surface of the n-type semiconductor substrate 51. Moreover, a p-side ohmic electrode 57 is provided on the p-type contact layer 56 and an n-side ohmic electrode 58 is formed on a back surface of the n-type semiconductor substrate 51.

Moreover, in the semiconductor laser of this embodiment, unlike any one of the semiconductor lasers of the embodiments which have been described, the p-type second clad layer is formed to have a convex ridge shape (a roof shape).

In a center portion of the p-type contact layer 56 in the optical oscillator direction, a slit 60 intersecting with the ridge 59 at right angles when two-dimensionally viewed, and the p-side ohmic electrode 57 is formed so as to cover the slit 60. Part of the p-type contact layer 56 in which the slit 60 is not located has a thickness of 4 μm. The depth of the slit 60 is 1.5 μm. The slit preferably as a depth at which the slit does not break through the p-type contact layer 56. If the slit 60, which intersects with a stripe at right angles, breaks through the p-type contact layer 56, laser characteristics are influenced.

In the semiconductor laser of this embodiment, as in the semiconductor laser of the first embodiment, distortion applied to the active layer 53 can be reduced and the performance of the semiconductor laser can be prevented. Moreover, the operating life of the semiconductor laser of this embodiment is longer than that of the known semiconductor laser.

Note that the ridge type semiconductor laser of this embodiment may have a structure in which an electrode is not provided in a slit. In that case, the same effects as those of the first embodiment can be achieved.

Moreover, in the semiconductor laser of this embodiment, even if a slit extending in the parallel direction to a ridge is provided as in the second embodiment, a plurality of slits are provided as in the third embodiment, or a cross-shaped slit is provided, the same effects can be achieved.

Moreover, in the ridge type semiconductor laser, as described in Japanese Laid-Open Publication No. 2000-68591, even if a ridge is generated in a side surface of a ridge portion, the ridge amount of the ridge portion is only about 0.2 μm. Thus, if the thickness of a metal electrode is set to be 1 μm or more, the ridge of about 0.2 μm generated in bonding with a solder is embedded in an alloy layer formed of the solder and gold. Accordingly, a concentration of distortion to the ridge portion can be eased.

### Fifth Embodiment

FIGS. 10A and 10B are perspective views illustrating mounting surfaces for a semiconductor laser according to a fifth embodiment of the present invention.

In this embodiment, a semiconductor material or a metal material is selectively deposited over the p-type contact layer 17 having a substantial flat surface to form a film, thereby obtaining the similar structure to that of the slit 20.

The structure according to this embodiment is preferably used, for example, when there is a concern that the thickness of the p-type contact layer 17 of the semiconductor laser 1 is so small that the slit 20, which is formed so as to cross the stripe 21 or extend in the parallel direction to the stripe 21, breaks through the p-type contact layer 17, and when a semiconductor lamination body which is difficult to be subjected to etching for forming the slit 20 is used.

In a first method for fabricating the semiconductor laser of this embodiment, as shown in FIG. 10A, a silicon nitride film, a silicon oxide film or the like is selectively formed on an upper surface of the normally formed, substantially flat p-type contact layer 17 so as to extend for example, in the direction in which the film crosses the stripe 21 and be located only on a region of the p-type contact layer 17 in which the slit 20 is desired to be formed. Next, on the upper surface of the p-type contact layer 17 including the film, a semiconductor layer 80 made of the same material as that of the p-type contact layer 17 or some other semiconductor material is, furthermore, formed so as to have a thickness of about 1 μm and then the previously formed silicon nitride or silicon film is removed using hydrofluoric acid or the like. Thus, the similar structure to that of the slit 20 can be finally formed. Next, a p-side ohmic electrode 18 is formed on the upper surface. Subsequent process steps of the formation of the p-side ohmic electrode 18 are performed in the same manner as in the first embodiment.

Moreover, in a second method for fabricating the semiconductor laser of this embodiment, as shown in FIG. 10B, a p-side ohmic electrode 18 which includes a Cr layer 81, a Pt layer 82, and an Au layer 83 stacked in this order from the bottom (i.e., from a surface of the p-type contact layer 17) in the same manner as in the first embodiment is formed on the normally formed, substantially flat p-type contact layer 17 having a thickness of about 1 μm. Thereafter, parts of the Au layer 83 located in a region in which a slit 20 is formed and in a region which is to be a periphery portion of the semiconductor laser 1 are removed by performing etching so that the Al layer 83 has a pattern shape. Next, an Au plating layer 84 is selectively formed only on an upper surface of the Au layer 83 having a pattern shape so as to have a thickness of 2 μm by plating, so that a step of 2 μm is formed between the upper surface of the p-type contact layer 17 and the upper layer of the Au plating layer 84. Thus, a slit 20 having a depth of 2 μm is finally formed. In this case, the reason why the part of the Au layer 83 to be the peripheral portion of the semiconductor laser 1 is removed is that the part of the Au layer 83 located in the peripheral portion of the semiconductor laser 1 becomes an obstruction in processing when the semiconductor laser 1 is later cleaved. Moreover, subsequent process steps are performed in the same manner as in the first embodiment.

In this embodiment, the metal layer selectively formed on the p-side ohmic electrode may be made of Ag, Ni and the like, in addition to Au. Moreover, a method for forming the metal layer may be some other method than plating.

In the semiconductor laser of this embodiment, the thickness of the Au plating layer 84 is preferably not less than 0.5 μm and not more than 10 μm in view of expelling an unnecessary solder material out of the slit 20 and also suppressing increase in fabrication costs.

According to the methods of this embodiment, the slit 20 having a desired shape can be formed without etching the p-type contact layer 17, so that the same effects as those of the first and second embodiment can be achieved. Specifically, by performing low pressure welding using a collet, the excessive solder layer 32 is easily expelled out, so that the solder material 32 spreads uniformly. Thus, application of nonuniform distortion to the semiconductor laser 1 can be prevented. Moreover, there is no need for etching an upper portion of the semiconductor lamination body of the semiconductor laser. Therefore, damages to the stripe 21 and other part of the semiconductor lamination body are not caused.

Note that in each of the first and second method of this embodiment, the direction and the location in which the slit 20 extends may be the same as those for the slit of each of the first through fourth embodiments. The effects achieved with the direction and the location in which the slit extends are the same as those in each of the first through fourth embodiments.

Note that the present invention is not limited to each of the embodiments described above and it is clear that each of the embodiments may be appropriately modified within the technical scope of the present invention. Moreover, the number, the location, the shape or the like of each of the above described members are not limited to each of the embodiments but may be appropriately changed to a preferable number, location, shape or the like when the present invention is exploited.

A semiconductor laser according to the present invention is a high-power, highly reliable semiconductor laser and is usefully applied to an optical pickup device in an optical disk apparatus dealing with, for example, CDs, DVDs and the like.

1. A semiconductor laser capable of outputting laser light, comprising in an upper surface thereof a slit having a concave shape and extending from one end to the other end.

2. The semiconductor laser of claim 1, further comprising:
a submount bonded to the upper surface; and
a bonding member for bonding the submount to the upper surface.

3. The semiconductor laser of claim 2, comprising:
a substrate;
a first clad layer of a first conductive type formed on a principal surface of the substrate;
an active layer capable of outputting the laser light formed on the first clad layer;
a second clad layer of a second conductive type formed on the active layer;
a current blocking layer formed on the second clad layer;
a third clad layer of the second conductive type formed on or over the second clad layer;
a contact layer formed of semiconductor of the second conductive type on the third clad layer; and
an ohmic electrode formed on or over the contact layer.

4. The semiconductor laser of claim 3, wherein a stripe is formed in the current blocking layer so as to extend in the direction in which the laser light is emitted, and
wherein the third clad layer is formed so as to fill at least the stripe.

5. The semiconductor laser of claim 3, wherein the slit is formed so as to be located in the contact layer and the ohmic electrode.

6. The semiconductor laser of claim 3, wherein the slit is provided in the contact layer and the ohmic electrode is not provided in the slit.

7. The semiconductor laser of claim 3, wherein the upper surface of the ohmic electrode is flat, and
wherein the semiconductor laser further includes a metal layer formed on the ohmic electrode having the slit provided therein.

8. The semiconductor laser of claim 7, wherein a peripheral portion of the metal layer is removed.

9. The semiconductor laser of claim 7, wherein the depth of the slit is 0.5 μm or more.

10. The semiconductor laser of claim 7, wherein the metal layer is any one of an Au plating layer, an Ag plating layer and an Ni plating layer.

11. The semiconductor laser of claim 3, further comprising a semiconductor layer formed so as to be located on the contact layer and under the ohmic electrode.

12. The semiconductor laser of claim 3, wherein the depth of the slit is smaller than the thickness of the contact layer.

13. The semiconductor laser of claim 3, wherein the thickness of the contact layer is 5 μm or less.

14. The semiconductor laser of claim 4, wherein the slit is provided so as to cross the stripe when two-dimensionally viewed.

15. The semiconductor laser of claim 14, wherein the slit is provided so as to cross the stripe at a center portion of the stripe in the long side direction when two-dimensionally viewed.

16. The semiconductor laser of claim 4, wherein the slit is provided so as to be parallel to the stripe and so as not to overlap with the stripe when two-dimensionally viewed.

17. The semiconductor laser of claim 15, wherein the slit is provided plural in number.

18. The semiconductor laser of claim 3, wherein a bonding portion of the ohmic electrode bonded with the bonding member is made of a material which does not form an alloy with the bonding member.

19. A method for forming a semiconductor laser including a first clad layer of a first conductive type formed on a principal surface of a substrate, an active layer capable of outputting the laser light formed on the first clad layer, a second clad layer of a second conductive type formed on the active layer, a current blocking layer formed on the second clad layer, a third clad layer of the second conductive type formed on or over the second clad layer, a contact layer formed of semiconductor of the second conductive type on the third clad layer, and an ohmic electrode formed on or over the contact layer, the method comprising the steps of:
a) forming, on the third clad layer, the contact layer including a slit having a concave shape and extending from one end to the other end; and
b) forming the ohmic electrode on the contact layer.

20. The method of claim 19, further comprising:
after the step b), the step of bonding an upper surface of the ohmic electrode and a submount with each other using a bonding member.

21. The method of claim 19, wherein the step a) includes
the step of depositing semiconductor over the third clad layer to form a first semiconductor layer,
the step of forming on the first semiconductor layer a resist having an opening, and
the step of performing wet etching or dry etching using the resist as a mask to form the slit.

22. A method for forming a semiconductor laser including a first clad layer of a first conductive type formed on a principal surface of a substrate, an active layer capable of outputting the laser light formed on the first clad layer, a second clad layer of a second conductive type formed on the active layer, a current blocking layer formed on the second clad layer, a third clad layer of the second conductive type formed on or over the second clad layer, a contact layer formed of semiconductor of the second conductive type on the third clad layer, a second semiconductor layer formed on the contact layer, and an ohmic electrode formed on the second semiconductor layer, the method comprising the step of:
c) forming on the contact layer the second semiconductor layer including a slit having a concave shape and extending from one end to the other end.

23. The method of claim 22, wherein the step c) includes
the step of covering the contact layer with a protection film and then removing the protection film so as to leave part of the protection film located in a region in which a slit is formed,
the step of depositing semiconductor over the contact layer to form the second semiconductor layer, and
the step of removing the part of the protection film.

24. A method for forming a semiconductor laser including a first clad layer of a first conductive type formed on a principal surface of a substrate, an active layer capable of outputting the laser light formed on the first clad layer, a second clad layer of a second conductive type formed on the active layer, a current blocking layer formed on the second clad layer, a third clad layer of the second conductive type formed on or over the second clad layer, a contact layer formed of semiconductor of the second conductive type on the third clad layer, and an ohmic electrode formed on or over the contact layer, the method comprising the steps of:
d) forming the ohmic electrode so as to have a flat upper surface, and
e) forming on the ohmic electrode a metal layer including a slit having a concave shape and extending from one end to the other end.

25. The method of claim 24, wherein in the step e), the metal layer is formed using plating.
